(19) United States
(12) Patent Application Publication
(10) Pub. No.: US 2019/0080949 A1
(43) Pub. Date: Mar. 14, 2019

(54) SOFT CHUCKING AND DECHUCKING FOR ELECTROSTATIC CHUCKING SUBSTRATE SUPPORTS

(71) Applicant: Applied Materials, Inc., Santa Clara, CA (US)

(72) Inventors: Wendell Glenn BOYD, JR., Morgan Hill, CA (US); Jim Zhongyi HE, San Jose, CA (US)

(21) Appl. No.: 15/811,352

(22) Filed: Nov. 13, 2017

Related U.S. Application Data
(60) Provisional application No. 62/556,147, filed on Sep. 8, 2017.

(51) Int. Cl. H01L 21/683; H01J 37/32; C23C 16/458

(52) U.S. Cl. CPC H01L 21/6833; C23C 16/4586; H01J 37/32715; H01J 37/32697

(57) ABSTRACT

Methods for chucking and de-chucking a substrate from an electrostatic chucking (ESC) substrate support to reduce scratches of the non-active surface of a substrate include simultaneously increasing a voltage applied to a chucking electrode embedded in the ESC substrate support and a backside gas pressure in a backside volume disposed between the substrate and the substrate support to chuck the substrate and reversing the process to de-chuck the substrate.

### CROSS-REFERENCE TO RELATED APPLICATIONS

This application claims priority to United States Provisional Application Serial No. 62/556,147 filed on Sep. 8, 2017, which is herein incorporated by reference in its entirety.

### BACKGROUND

### Field

Embodiments described herein generally relate to semiconductor manufacturing, in particular, to methods of chucking and de-chucking a substrate to and from a substrate support disposed in a processing chamber.

### Description of the Related Art

Electrostatic chucking (ESC) substrate supports are commonly used in semiconductor manufacturing to securely hold a substrate in a processing position, within a processing volume of a processing chamber, by means of an electrostatic chucking (ESC) force. The chucking force is a function of the potential between a DC voltage provided to a chucking electrode embedded in a dielectric material of the substrate support and a substrate disposed on a surface of the dielectric material.

Often, the substrate support is used to maintain the substrate at a desired temperature, or within a desired range of temperatures, through heat transfer between the dielectric material of the substrate support and the substrate disposed thereon. For example, some substrate supports comprise a heating element disposed in the dielectric material thereof that is used to heat the substrate support, and thereby the substrate, to a desired temperature before processing and/or to maintain the substrate at a desired temperature during processing. For other semiconductor manufacturing processes, it is desirable to cool the substrate during the processing thereof and the substrate support is thermally coupled to a cooling base, typically comprising one or more cooling channels having a cooling fluid flowing therethrough, that is used to cool the cooling base and thereby the substrate support, and thereby the substrate, disposed thereon.

Typically, a low pressure atmosphere in a processing volume of a processing chamber results poor thermal conduction between the dielectric material of the substrate support and the substrate thereby reducing the substrate support's effectiveness in heating or cooling the substrate. Therefore, in some processes, a thermally conductive inert gas, such as helium, is introduced into a backside volume disposed between a non-active surface of the substrate and the substrate support to improve heat transfer therebetween. The higher pressure of the backside volume (backside pressure), when compared to the pressure in the processing volume (processing pressure), exerts a backside force on the substrate that is opposite of the chucking force exerted by the chucking electrode, where the difference between the chucking force and the backside force comprises the contact force between the substrate and the substrate support surface.

Unfortunately, excessive contact force between the substrate and the substrate support surface result in undesirable scratches on the non-active surface of the substrate and/or undesirable wear of the dielectric material of the substrate support. Particulate materials produced from the scratches and/or wear of the substrate support eventually transfer from the substrate support and/or the non-active surface of the substrate to an active surface of the substrate and/or other substrates through subsequent handling and/or processing operations thereby ultimately suppressing device yield from a substrate.

Accordingly, what is needed in the art are improved electrostatic chucking and de-chucking methods.

### SUMMARY

Embodiments described herein generally relate to plasma assisted or plasma enhanced processing methods. More specifically, embodiments described herein relate to electrostatic chucking (ESC) and de-chucking methods to reduce substrate scratches and defects related to electrostatic chucking before, during, and after plasma assisted or plasma enhanced semiconductor manufacturing processes.

In one embodiment, a method for chucking a substrate includes positioning the substrate on a substrate support, wherein the substrate support is disposed in the processing volume of a processing chamber, flowing a first gas into the processing volume, forming a processing plasma from the first gas, and chucking the substrate to the substrate support. Chucking the substrate to the substrate support includes applying a first chucking voltage to a chucking electrode disposed in the substrate support, flowing a second gas into a backside volume disposed between the substrate and the substrate support, and increasing the chucking voltage from the first chucking voltage to a second chucking voltage while simultaneously increasing a backside pressure in the backside volume from a first backside pressure to a second backside pressure. In some embodiments, the method further includes de-chucking the substrate from the substrate support by decreasing the backside pressure from the second pressure to a third pressure while simultaneously decreasing the second chucking voltage to a third voltage.

In another embodiment, a substrate chucking method includes flowing a first gas into a first volume of a processing chamber, forming a processing plasma from the first gas, applying a first chucking voltage to a chucking electrode embedded in a dielectric material of a substrate support, the substrate support having a substrate disposed thereon, providing a second gas to a second volume disposed between the substrate support and the substrate, and increasing the chucking voltage from the first chucking voltage to a second chucking voltage while simultaneously increasing a pressure of the second gas in the second volume from a first pressure to a second pressure.

In another embodiment, a substrate chucking method includes flowing a first gas into a processing volume of a processing chamber, the processing chamber having a substrate support disposed therein, forming a plasma of the processing gas, and chucking a substrate to the substrate support. Chucking the substrate to the substrate support includes applying a first voltage to a chucking electrode embedded in a dielectric material of the substrate support, flowing a second gas into a backside volume disposed between a surface of the substrate support and a non-active surface of a substrate disposed thereon, and concurrently increasing a pressure in the backside volume from a first pressure to a second pressure and the voltage applied to the chucking electrode from the first voltage to a second voltage.

Benefits of the embodiments described herein include significant reductions in the contract force between the substrate and the substrate support during chucking and de-chucking. Reducing the contact force reduces the number and size of undesirable scratches on the non-active surface of the substrate and reduces wear of the substrate support surface, which, in turn reduces particulate material that would otherwise eventually contaminate the active surface or the substrate or other substrates to suppress the device yield thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a processing chamber used to practice the methods described herein, according to one embodiment.

FIG. 2 is a close up sectional view of a portion of the substrate support used in the processing chamber of FIG. 1.

FIG. 3A is a flow diagram of a method for chucking a substrate to a substrate support, according to one embodiment.

FIG. 3B shows the chucking voltage and backside volume pressure during application of the method described in FIG. 3A.

### DETAILED DESCRIPTION

Embodiments described herein generally relate to plasma assisted or plasma enhanced processing methods. More specifically, embodiments described herein relate to electrostatic chucking (ESC) methods to reduce substrate scratches and defects related to electrostatic chucking during plasma assisted or plasma enhanced semiconductor manufacturing processes.

Typically, a low pressure atmosphere in a processing volume of a plasma processing chamber results in poor thermal conduction between a substrate and the dielectric material of an ESC substrate support that the substrate is disposed on during processing. To improve heat transfer between the substrate and the ESC substrate support, a thermally conductive inert gas, such as helium, is introduced into a substrate backside volume disposed therebetween so that the pressure of the gas in the backside volume exceeds the gas pressure of the processing volume. Thus, the chucking force applied to the substrate by the chucking electrode must exceed the force exerted on the substrate by the gas in the backside volume to prevent the substrate from moving on the chuck. The difference between the chucking force pulling the substrate towards the substrate support and the backside force (the force exerted on the substrate by the gas in the backside volume) pushing the substrate away from the substrate support yields the contact force between the substrate and the substrate support surfaces in direct contact therewith. Undesirable scratching of the substrate by the substrate support results when the contact force between the substrate and the substrate support significantly exceeds the minimum contact force required to securely hold the substrate in position for the processing thereof. Material produced from the scratches, which become loose particles on the non-active surface of the substrate and on the substrate support, eventually transfer to the active surface of the substrate or another substrate during handling or subsequent processing thereof. This increased defectivity on the active surface of the substrate negatively impacts the device yield thereof.

Conventional chucking methods typically apply a chucking voltage to the chucking electrode before pressurizing of the backside volume by flowing a gas thereinto. Conventional de-chucking methods typically depressurize the backside volume before releasing the substrate from the substrate support by stopping the chucking voltage applied to the chucking electrode. Therefore, the contact forces between the substrate and the substrate support surfaces in direct contact therewith are typically highest during conventional chucking and de-chucking steps and significantly and undesirably exceed the minimum contact forces required to securely hold the substrate to the substrate support. To reduce scratching and defects related with conventional chucking and de-chucking steps, the methods herein provide for simultaneous ramping of a chucking voltage provided to a chucking electrode disposed in the substrate support and the pressure of gas in the backside volume disposed between the substrate and the substrate support.

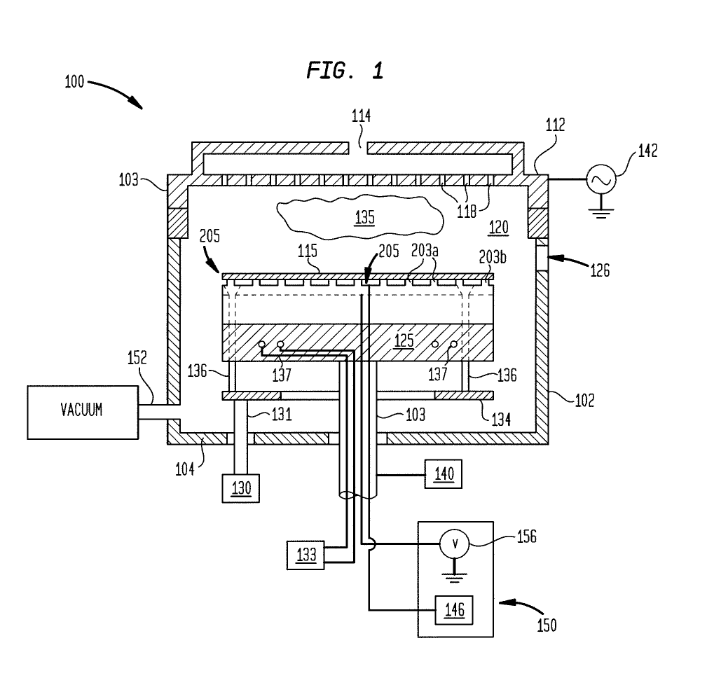

FIG. 1 is a schematic sectional view of a processing chamber 100 used to practice the methods described herein, according to one embodiment. Typically, the processing chamber 100 is a plasma processing chamber, such as a plasma etch chamber, a plasma-enhanced deposition chamber, for example a plasma-enhanced chemical vapor deposition (PECVD) chamber or a plasma-enhanced atomic layer deposition (PEALD) chamber, or a plasma based ion implant chamber, for example a plasma doping (PLAD) chamber. However, the methods described herein can be used with any processing chamber using an ESC substrate support where gas is provided to a volume present between the ESC substrate support and a substrate disposed thereon.

Herein, the processing chamber 100 described is a schematic representation of a CVD processing chamber, and it includes a chamber lid 103, one or more sidewalls 102, and a chamber bottom 104 which define a processing volume 120. A showerhead 112, having a plurality of openings 118 disposed therethrough, is disposed in the chamber lid 103 and is used to uniformly distribute processing gases from a gas inlet 114 into the processing volume 120. The showerhead 112 is coupled to a first power supply 142, such as an RF or VHF power supply, which ignites and maintains a processing plasma 135 composed of the processing gases through capacitive coupling therewith. The processing volume 120 is fluidly coupled to a vacuum, such as to one or more dedicated vacuum pumps, through a vacuum outlet 113 which maintains the processing volume 120 at sub-atmospheric conditions and evacuates processing and other gases therefrom. A substrate support assembly 160, disposed in the processing volume 120 is disposed on a support shaft 124 sealingly extending through the chamber bottom 104. The support shaft 124 is coupled to a controller 140 that raises and lowers the support shaft 124, and the substrate support assembly 160 disposed thereon, to facilitate processing of the substrate 115 in the processing chamber 100.

The substrate 115 is loaded into the processing volume 120 through an opening 126 in one of the one or more sidewalls 102, which is conventionally sealed with a or door or a valve (not shown) during substrate 115 processing. A plurality of lift pins 136 disposed above, but engageable with, a lift pin hoop 134 are movably disposed through the substrate support assembly 160 to facilitate transferring of the substrate 115 thereto and therefrom. The lift pin hoop 134 is coupled to lift hoop shaft 131 sealingly extending through the chamber bottom, which raises and lowers the lift pin hoop 134 by means of an actuator 130. When the lift pin hoop 134 is in a raised position, the plurality of lift pins 136 are contacted from below and moved to extend above the surface of the substrate support 127 lifting the substrate 115 therefrom and enabling access to the substrate 115 by a robot handler. When the lift pin hoop 134 is in a lowered position the tops of the plurality of lift pins 136 are flush with, or below, the substrate support surface 203 and the substrate rests on a plurality of protrusions 203a thereof.

Typically, the substrate support assembly 160 includes a cooling base 125 and a substrate support 127 thermally coupled to, and disposed on, the cooling base 125. The cooling base 125 is used to regulate the temperature of the substrate support 127, and the substrate 115 disposed on the substrate support, during processing. The cooling base 125 includes one or more fluid conduits 137 disposed therein that are fluidly coupled to, and in fluid communication with, a coolant source 133, such as a refrigerant source or water source. Typically, the cooling base 125 is formed of a corrosion resistant thermally conductive material, such as a corrosion resistant metal, for example aluminum, an aluminum alloy, or stainless steel, and is thermally coupled to the substrate support 200 with an adhesive or by mechanical means.

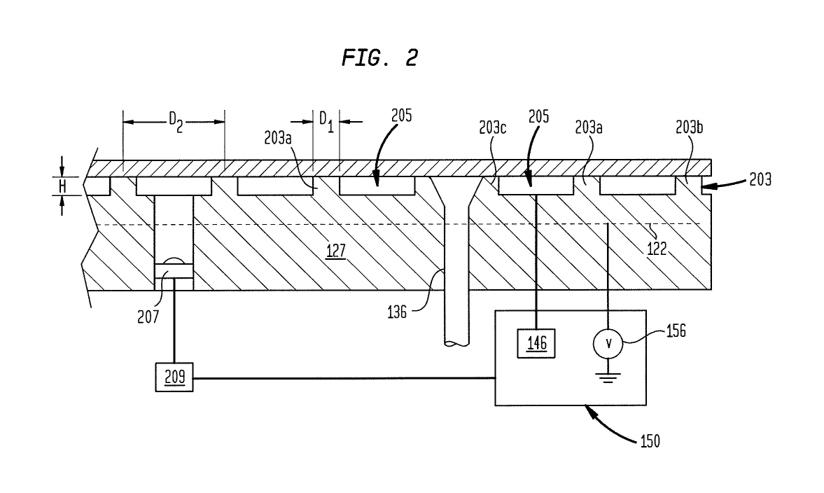

FIG. 2 is a close up sectional view of a portion of the substrate support 127 shown in FIG. 1. The substrate support 127 is formed from a dielectric material, such as a ceramic material, such as a metal oxide or metal nitride ceramic material, for example Al₂O₃, AlN, Y₂O₃, mixtures thereof, and combinations thereof. The substrate support 127 includes a chucking electrode 122, embedded in the dielectric material thereof, planarly disposed parallel to the substrate support surface 203. The substrate support surface 203 includes a plurality of protrusions 203a, a sealing lip 203b, a plurality of lift pin opening lips 203c, and one or more recessed surfaces 203d that define a backside volume 205 when the substrate 115 is chucked to the substrate support 127. The plurality of protrusions 203a herein include a plurality of cylindrical shaped mesas having a diameter D₁ of between about 500 μm and about 5 mm. The plurality of protrusions 203a are spaced apart from one another by a center to center (CTC) spacing D₂ of between about 5 mm and about 20 mm. The sealing lip 203b is concentrically disposed on the substrate support 127 and is proximate to the outer circumference thereof. Each of the plurality of lift pin opening lips 203c comprise an annular ring coaxially disposed about a respective lift pin opening formed in the dielectric material of the substrate support 127. The plurality of protrusions 203a, the sealing lip 203b, and the lift pin opening lips 203c extend above the recessed surface 203d by a height H of between about 3 um and about 700 um. The plurality of protrusions 203ca at least, hold the substrate 115 apart from the recessed surface 203d when the substrate 115 is chucked to the substrate support 127 which allows gas to flow therebetween. The sealing lip 203b and the lift pin opening lips 203c prevent gases from flowing between the processing volume 120 and the backside volume 205 when the substrate 115 is disposed thereon. An inert thermally conductive gas, such as helium, is provided to the backside volume 205 from a gas source 146. The inert gas thermally couples the substrate 115 to the substrate support surface 203 and increases the heat transfer therebetween. Typically, the gas pressure in the backside volume 205 is between about 1 Torr and about 100 Torr, such as between about 1 Torr and about 20 Torr, during plasma processing of the substrate 115. In some embodiments, the substrate support 127 further includes one or more sensors 207 that measure a deflection of the substrate 115 when a chucking voltage is applied thereto. The deflection of the substrate 115 is communicated to a controller 209 which determines the contact force between the substrate 115 and the substrate support 127 and adjusts the chucking voltage accordingly.

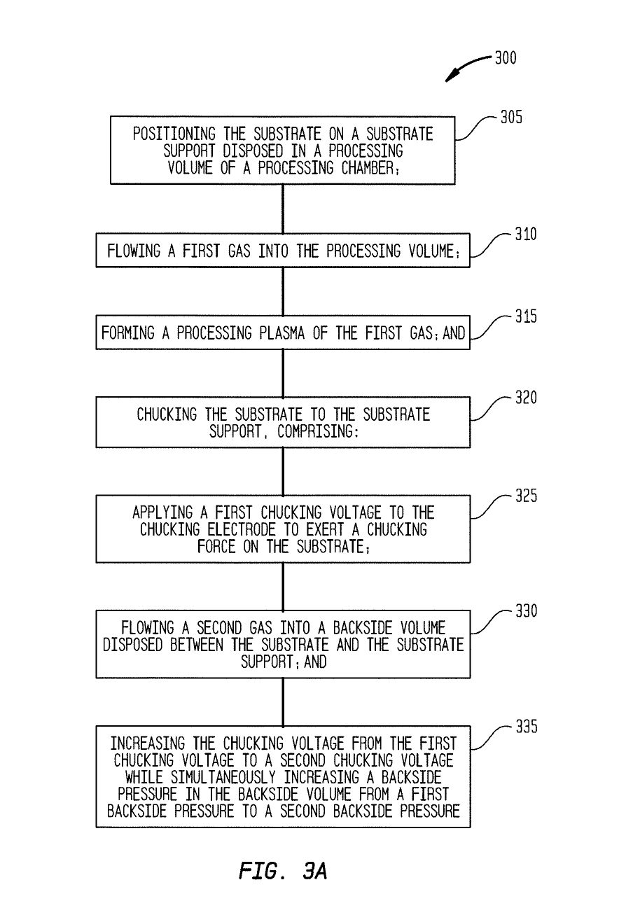

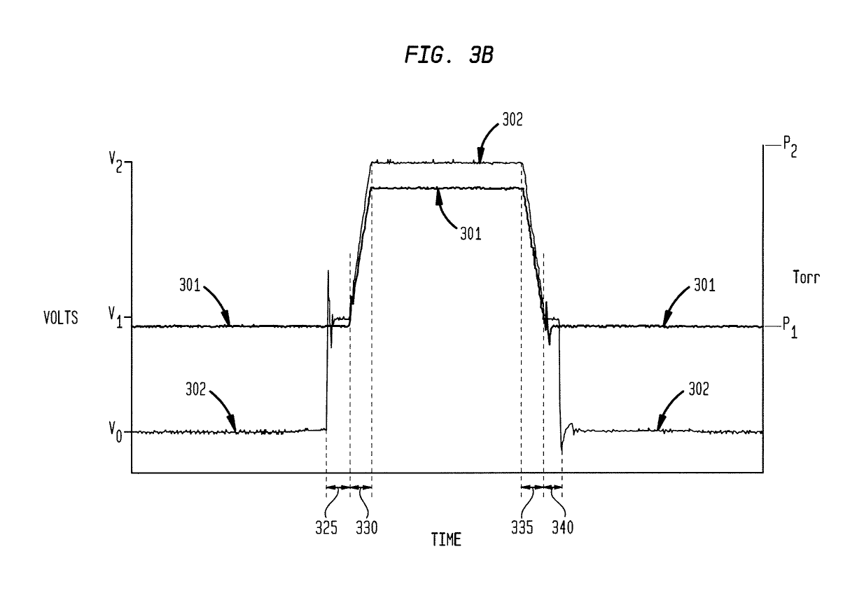

FIG. 3A is a flow diagram of a method 300 of chucking a substrate to a substrate support, according to one embodiment. FIG. 3B shows the chucking voltage 301 and the backside volume pressure 302 during application of the method 300 described in FIG. 3A. The method 300 begins at activity 305 with positioning a substrate on a substrate support disposed in a processing volume of a processing chamber. Typically, the substrate support comprises a dielectric material having a recessed surface, a plurality of protrusions extending from the recessed surface, and a sealing lip extending from the recessed surface disposed proximate to an outer circumference of the substrate support. Herein, the substrate support further includes a plurality of lift pin opening lips extending from the recessed surface where each of the lift pin opening lips comprises an annular ring concentrically disposed about a respective lift pin opening formed in the dielectric material of the substrate support. The non-active surface of the substrate, the sealing lip, the lift pin opening lips, and the recessed surface define a backside volume disposed between the substrate and the recessed surface where the substrate is space apart from the recessed surface by the height of the plurality of protrusions that the substrate rests upon. The substrate support herein further includes a chucking electrode planarly disposed in the dielectric material of the substrate support and parallel to the recessed surface thereof.

The method 300 continues at activity 310 with flowing a first gas into the processing volume and at 315 with forming a plasma of the first gas.

The method 300 continues at activity 320 with chucking the substrate to the substrate support which comprises applying a first chucking voltage V₁ to the chucking electrode to exert a chucking force on the substrate at activity 325 of the method 300. Applying the first chucking voltage V₁ to the chucking electrode pulls the substrate into uniform contact with the sealing lip and the plurality of lift pin opening lips with enough force to fluidly isolate the backside volume from the processing volume of the processing chamber. After applying the first chucking voltage V₁ at activity 325 the method 300 continues at activity 330 with flowing a second gas, typically a thermally conductive inert gas such as helium, into the backside volume. The method 300 continues at activity 335 with increasing the first chucking voltage V₁ to a second chucking voltage V₂ while simultaneously increasing the pressure in the backside volume from a first backside pressure P₁ to a second backside pressure P2. In embodiments herein, the first chucking voltage V₁ is between about 100 V and about 1000 V and the second chucking voltage V₂ is between about the first voltage and about 3000 V, for example between about the first chucking voltage V₁ and about 2000 V. Typically, the pressures in the backside volume are between about 1 Torr and about 100 Torr, such as between about 1 Torr and about 20 Torr. Herein, the rate of voltage increase between the first chucking voltage and the second chucking voltage and the rate of pressure increase between the first pressure and the second pressure is substantially constant. The rate of voltage increase is between about 50 V/s and about 800 V/s and the rate of pressure increase is between about 0.1 Torr/s and about 20 Torr/s, such as between about 0.2 Torr/s and about 10 Torr/s.

In some embodiments, the method further includes de-chucking the substrate from the substrate support by decreasing the backside pressure from the second backside pressure to a third backside pressure while simultaneously decreasing the second chucking voltage to a third chucking voltage. Typically, the third backside pressure is the same as the gas pressure in the processing volume and the third chucking voltage is about 0 V.

In some embodiments, processing of the substrate comprises applying a bias voltage to a bias electrode disposed in the substrate support. To attract ions of the plasma in the direction of the substrate on the substrate support. In those embodiments, applying the bias voltage begins after chucking of the substrate to the substrate support and ends before de-chucking of the substrate from the substrate support.

The methods described herein provide for significant reductions in undesirable scratches to the non-active surface of a substrate compared to conventional methods by minimizing the contact force between the substrate and substrate support surfaces during chucking and de-chucking operations.

While the foregoing is directed to embodiments of the present disclosure, other and further embodiments of the disclosure may be devised without departing from the basic scope thereof, and the scope thereof is determined by the claims that follow.

1. A method for chucking a substrate, comprising:
positioning the substrate on a substrate support, wherein the substrate support is disposed in a processing volume of a processing chamber;
flowing one or more first gases into the processing volume;
forming a processing plasma of the one or more first gases; and
chucking the substrate to the substrate support, comprising:
applying a first chucking voltage to a chucking electrode disposed in the substrate support to exert a chucking force on the substrate;
flowing a second gas comprising helium into a backside volume disposed between the substrate and the substrate support; and
increasing the chucking voltage from the first chucking voltage to a second chucking voltage while simultaneously increasing a backside pressure in the backside volume from a first backside pressure to a second backside pressure.

2. The method of claim 1, wherein the substrate support further comprises a recessed surface and a sealing lip extending from the recessed surface, wherein the substrate, the sealing lip, and the recessed surface define the backside volume.

3. The method of claim 2, wherein the substrate support is formed of a dielectric material selected from the group consisting of Al2O3, AlN, Y2O3, and combinations thereof.

4. The method of claim 2, wherein the sealing lip comprises an annular ring concentrically disposed on the recessed surface proximate to an outer circumference of the substrate support.

5. The method of claim 4, wherein the substrate support further comprises a plurality of protrusions extending beyond the recessed surface by a height between about 3 μm and about 700 μm.

6. The method of claim 1, wherein the second backside pressure is between about 1 Torr and about 100 Torr.

7. The method of claim 6, wherein the first chucking voltage is between about 100 V and about 1000 V, and wherein the second chucking voltage is between the first chucking voltage and about 2000 V.

8. The method of claim 1, further comprising de-chucking the substrate from the substrate support by decreasing the backside pressure from the second backside pressure to a third backside pressure while simultaneously decreasing the second chucking voltage to a third chucking voltage.

9. The method of claim 1, wherein the substrate support is disposed on a cooling base formed of metal.

10. The method of claim 1, wherein applying the first chucking voltage to the chucking electrode fluidly isolates the backside volume from the processing volume.

11. The method of claim 1, wherein the rate of voltage increase from the first chucking voltage to the second chucking voltage is substantially constant.

12. The method of claim 10, wherein the second gas consists of helium.

13. The method of claim 3, wherein the substrate support further comprises one or more annular rings extending from the recessed surface, wherein the one or more annular rings are coaxially disposed about one or more respective openings formed in the dielectric material of the substrate support.

14. A substrate chucking method, comprising:
flowing one or more first gases into a first volume of a processing chamber;
forming a processing plasma from the one or more first gases;
applying a first chucking voltage to a chucking electrode embedded in a dielectric material of a substrate support, the substrate support having a substrate disposed thereon;
providing a second gas comprising helium to a second volume disposed between the substrate support and the substrate; and
increasing the chucking voltage from the first chucking voltage to a second chucking voltage while simultaneously increasing a pressure of the second gas in the second volume from a first pressure to a second pressure.

15. The method of claim 14, further comprising de-chucking the substrate from the substrate support by decreasing the pressure of the second gas in the second volume from the second pressure to a third pressure while simultaneously decreasing the second chucking voltage to a third voltage.

16. The method of claim 14, wherein the rate of voltage increase from the first chucking voltage to the second chucking voltage is substantially constant.

17. The method of claim 16, wherein applying the first chucking voltage to the chucking electrode fluidly isolates the second volume from the first volume.

18. A substrate chucking method, comprising:
flowing one or more process gases into a processing volume of a processing chamber, the processing chamber having a substrate support disposed therein;
forming a plasma of the one or more process gases; and
chucking a substrate to the substrate support, comprising:
applying a first voltage to a chucking electrode embedded in a dielectric material of the substrate support;
flowing helium gas into a backside volume disposed between a surface of the substrate support and a non-active surface of a substrate disposed thereon; and
concurrently increasing a pressure in the backside volume from a first pressure to a second pressure and the voltage applied to the chucking electrode from the first voltage to a second voltage.

19. The method of claim 18, wherein applying the first voltage to the chucking electrode fluidly isolates the backside volume from the processing volume.

20. The method of claim 19, further comprising de-chucking the substrate from the substrate support by decreasing the pressure in the backside volume from the second pressure to a third pressure while simultaneously decreasing the second voltage to a third voltage.
